(19) United States
(12) Patent Application Publication
(10) Pub. No.: US 2020/0344904 A1
(43) Pub. Date: Oct. 29, 2020

(54) WATERPROOF STRUCTURE FOR VENTILATION OPENING IN ELECTRONIC EQUIPMENT, HOUSING, AND ELECTRONIC EQUIPMENT

(71) Applicant: NEC Platforms, Ltd., Kawasaki-shi, Kanagawa (JP)

(72) Inventor: Yuta SASAKI, Kanagawa (JP)

(73) Assignee: NEC Platforms, Ltd., Kawasaki-shi, Kanagawa (JP)

(21) Appl. No.: 16/960,732

(22) PCT Filed: Dec. 18, 2018
(86) PCT No.: PCT/JP2018/046476

§ 371 Date: Jul. 8, 2020

(30) Foreign Application Priority Data
Jan. 11, 2018 (JP) 2018-002378

(51) Int. Cl. H05K 5/03; H05K 7/20

(52) U.S. Cl. CPC H05K 5/03; H05K 7/20127

(57) ABSTRACT

A waterproof structure formed at a ventilation opening 11 provided in the top surface of a housing 10 in electronic equipment has a first filter 61 attached to the ventilation opening 11 with an inclination along a depth direction D of the housing 10. The first filter 61 is configured from a hydrophobic, water-repellent, and breathable hydromesh layer.

### TECHNICAL FIELD

The present invention relates to a waterproof structure for a ventilation opening of electronic equipment.

### BACKGROUND ART

As electronic equipment, there is known, for example, a gate device arranged adjacent to an entrance/exit gate. The gate device is a device for determining admission or denial of entrance and exit based on a security code or personal authentication information inputted thereto and controlling the gate based on a result of determination. The gate device is a type of information processing device comprising a CPU (Central Processing Unit) for carrying out arithmetic processing of information in accordance with a program, an information storage unit for memorizing information, an input/output interface for a signal representative of information, and a housing accommodating those devices.

The information processing device such as the gate device is often provided with cooling means because heat is generated following an operation. Among the cooling means, air-cooling means using air as a coolant includes those for forcibly circulating air by a fan and those for naturally circulating air by convection without using the fan. In the latter air-cooling means, a housing is provided with a ventilation opening in order to discharge air heated to high temperature in response to heat conduction from a heat generating portion such as the CPU and, conversely, to suck outside air. The ventilation opening is preferably formed on a top surface of the housing so as to efficiently carry out ventilation.

The ventilation opening of the housing allows communication between the inside and the outside of the housing and, therefore, is desirably provided with means for preventing intrusion of unnecessary moisture, dust, and foreign substances into the housing. In particular, in case of a gate device which may be used outdoors, the means for preventing intrusion of moisture or the like is essential.

Each of Patent Literatures 1 and 2 discloses electronic equipment having a waterproof structure for a ventilation opening. The waterproof structure for the ventilation opening disclosed in Patent Literature 1 has a hydrophobic porous material layer configured to cover the ventilation opening formed on a top surface of a housing. The waterproof structure for the ventilation opening disclosed in Patent Literature 2 has a roof member configured to cover the ventilation opening formed on a top surface of a housing, and filters formed at exhaust ports on opposite sides of the roof member.

### PRIOR ART LITERATURE(S)

### Patent Literature(s)

Patent Literature 1: JP 2006-231168 A

Patent Literature 2: JP 2000-037006 A

### SUMMARY OF THE INVENTION

### Problems to be Solved by the Invention

The hydrophobic porous material layer disclosed in Patent Literature 1 may also be called a waterproof moisture-permeable film and may not always be sufficient in breathability although waterproofness and moisture permeability are excellent. The waterproof structure disclosed in Patent Literature 2 may not always be sufficient in regard to breathability in a height direction of the housing because the ventilation opening is provided with the roof member which itself has no breathability at all.

Thus, including those disclosed in Patent Literatures 1 and 2, the waterproof structure for the ventilation housing of the electronic equipment according to the related art of the present invention has a room for improvement in view of breathability. Therefore, it is desired to provide a waterproof structure for a ventilation opening of electronic equipment excellent in both breathability and waterproofness.

It is therefore an object of the present invention to provide a waterproof structure for a ventilation housing of electronic equipment excellent in both breathability and waterproofness.

It is another object of the present invention to provide a housing having the above-mentioned waterproof structure for the ventilation opening of the electronic equipment.

It is still another object of the present invention to provide electronic equipment having the above-mentioned housing.

### Means to Solve the Problem

According to one aspect of this invention, there is provided a waterproof structure provided at a ventilation opening formed on a top surface of a housing of electronic equipment, in which the water proof structure comprises a first filter mounted to the ventilation opening to be inclined in a depth direction or a width direction of the housing, in which the first filter comprises a hydromesh layer having a hydrophobic or a water-repellent property and breathability.

According to another aspect of this invention, there is provided a housing of electronic equipment, comprising the above-mentioned waterproof structure for the ventilation opening of the electronic equipment.

According to still another aspect of this invention, there is provided electronic equipment having the above-mentioned housing.

### Effect of the Invention

The waterproof structure for the ventilation housing of the electronic equipment according to the present invention is excellent in both breathability and waterproofness.

### BRIEF DESCRIPTION OF THE DRAWINGS

FIG. 1 is a perspective view of a gate device to which a waterproof structure for a ventilation opening of electronic equipment according to an embodiment of the present invention is applicable.

FIG. 2 is a perspective view of a main part of the waterproof structure for the ventilation opening of the electronic equipment according to the embodiment of the present invention.

FIGS. 3 (a) and (b) are schematic sectional views for describing an operation of the waterproof structure for the ventilation opening of the electronic equipment according to the embodiment of the present invention.

### MODE FOR EMBODYING THE INVENTION

Hereinafter, a waterproof structure for a ventilation opening of electronic equipment according to the present invention will be described with reference to the drawings.

In the figure, a symbol W represents a width direction (including a leftward direction W1 and a rightward direction Wr) of a housing of the electronic equipment to which the waterproof structure for the ventilation opening is applicable, a symbol H represents a height direction (including a downward direction Hl and an upward direction Hu) of the housing, and a symbol D represents a depth direction (including a frontward direction Df and a rearward direction Dr) of the housing.

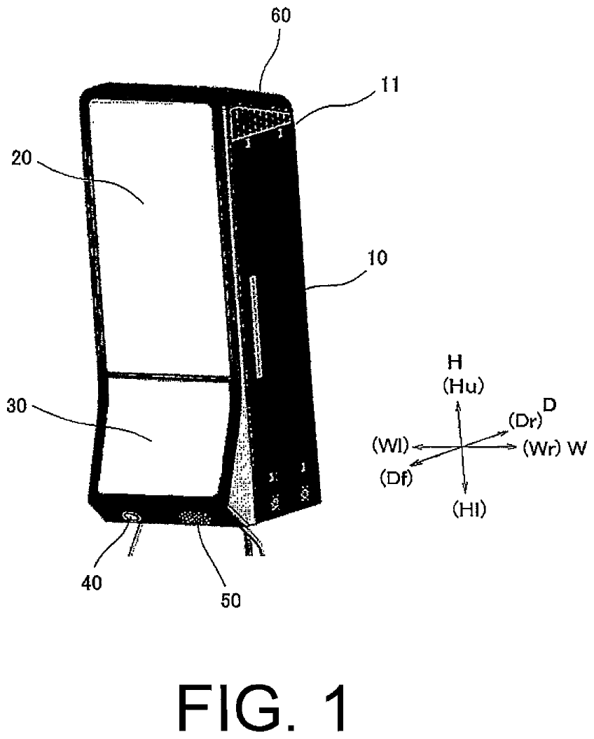

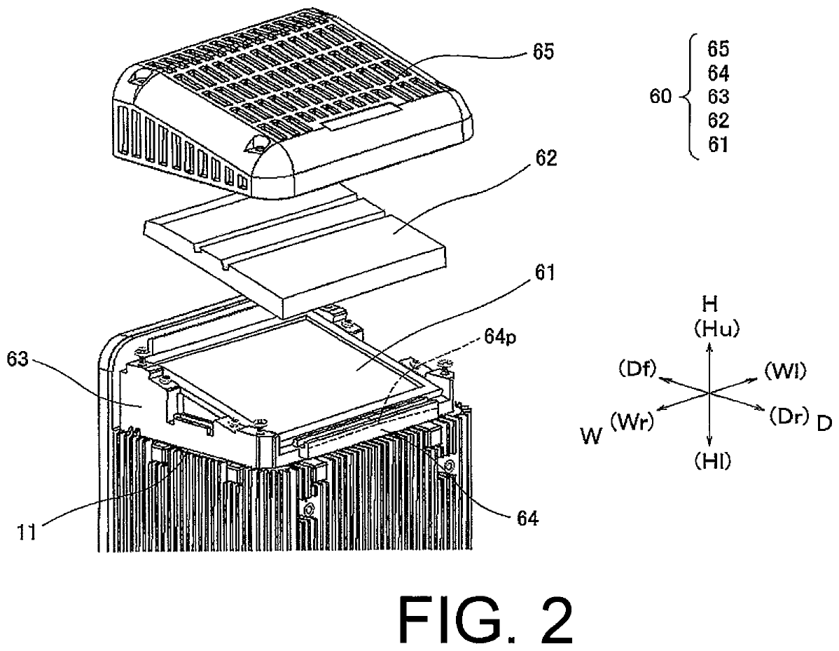

Referring to FIGS. 1 to 3, a waterproof structure 60 according to an embodiment of the present invention is applied to a ventilation opening 11 of a housing 10 of a gate device as electronic equipment. The gate device is arranged adjacent to an entrance/exit gate.

The gate device comprises a circuit board 71, a CPU 72 which is mounted to the circuit board 71 and which is for carrying out arithmetic processing of information in accordance with a software program, an information storage unit (not shown) for memorizing information including the software program also, an input/output interface for a signal representative of information including personal authentication information also, and a housing 10 accommodating those devices. The input/output interface comprises a touch panel display 20, a touch pad 30 for contactless communication, a speaker microphone 50, and a power supply switch 40. The gate device determines admission or denial of entrance and exit based on a security code inputted from the touch panel display 20 or the personal authentication information inputted via the touch pad 30, and controls a gate based on a result of determination.

The gate device is provided with cooling means because the CPU 72 or the like generates heat following an operation. The cooling means naturally circulates air without using a fan. In order to discharge air heated to high temperature in response to heat conduction from a heat generating portion such as the CPU 72 and, conversely, to suck outside air, the housing 10 is provided with the ventilation opening 11. The ventilation opening 11 is formed on a top surface of the housing 10 in a height direction H in order to perform efficient ventilation. The CPU 72 is accommodated in the housing 10 so that an upper part of the housing 10 in the height direction H faces the ventilation opening 11.

The waterproof structure 60 according to the embodiment of the present invention comprises a first filter 61, a second filter 62, a frame member 63, a gutter portion 64, and a top cover 65.

The first filter 61 is fitted to the ventilation opening 11 of the housing 10 to be inclined in a depth direction D of the housing 10. The first filter 61 comprises a hydromesh layer having a hydrophobic or a water-repellent property and breathability.

The second filter 62 is mounted to the first filter 61 to be stacked thereon. The second filter 62 comprises a foam layer having water absorbability and breathability.

As a comparative example, for instance, a hydrophobic porous material layer (waterproof moisture-permeable film) such as Gore-Tex (registered trademark), is a material preventing intrusion of water and allowing passage of inside air but is not always sufficient in breathability although waterproofness is excellent.

In comparison, the hydromesh layer used as the first filter 61 in the present invention is excellent in both waterproofness and breathability. However, water may possibly pass through when high water pressure is applied. On the other hand, the hydromesh layer has a performance of retaining moisture under surface tension. Therefore, in the present invention, the moisture retained on a surface of the first filter 61 under surface tension is slipped down to be discharged by arranging the first filter 61 with a slope.

It is noted that the hydromesh layer forming the first filter 61 is, for example, meshed polyester fiber and may also be called a high-density mesh cloth.

Furthermore, the second filter 62 comprising the foam layer is stacked as an upper layer on the hydromesh layer which may allow passage of water under high water pressure. Thus, water pressure is sufficiently reduced before the moisture reaches the first filter 61. In addition, as a side effect, the foam layer also prevents intrusion of dust.

The foam layer forming the second filter 62 is, for example, urethane foam and has an open-cell foam structure in which air bubbles are interconnected. The foam layer allows a gas or a liquid to pass therethrough while meandering.

Therefore, the waterproof structure 60 according to the embodiment of the present invention simultaneously achieves excellent breathability of exhausting heat inside the housing by natural convection and excellent waterproofness of causing the incoming moisture to be reduced in pressure, to be repelled, to flow down, and to be discharged.

The frame member 63 is fitted to the ventilation opening 11 of the housing 10 and supports the first filter 61 so that the first filter is inclined in the depth direction D of the housing 10.

The gutter portion 64 extends below a downslope edge of the first filter 61 in parallel to the downslope edge. The gutter portion 64 receives the moisture flowing down from the surface of the first filter 61 and discharges the moisture in an extending direction (width direction W). The frame member 63 integrally has the gutter portion 64.

The gutter portion 64 extends below the downslope edge of the first filter 61 along the downslope edge, i.e., extends in the width direction W of the housing 10. The gutter portion 64 receives the moisture flowing down from the surface of the first filter 61 and discharges the moisture in the extending direction (width direction W). In particular, in this embodiment, a bottom surface of the gutter portion 64 is inclined downward towards opposite ends from a center in the extending direction (width direction W) as a peak 64p. With the above-mentioned structure, the moisture is discharged from left and right side portions at a rear part of the housing so that the moisture is not retained on a rear surface of the housing. Accordingly, the housing of the electronic equipment can be fixed to a wall surface.

The top cover 65 is fitted to the housing 10 to cover the first filter 61 and the second filter 62. The top cover 65 has a mesh-like or a grid-like shape having a plurality of holes formed at least on an upper surface thereof. By providing the top cover 65, the first filter 61 and the second filter 62 are prevented from sticking of a foreign substance or from being tampered.

Next, description will be made of an operation of the waterproof structure for the ventilating opening of the electronic equipment according to the embodiment of the present invention.

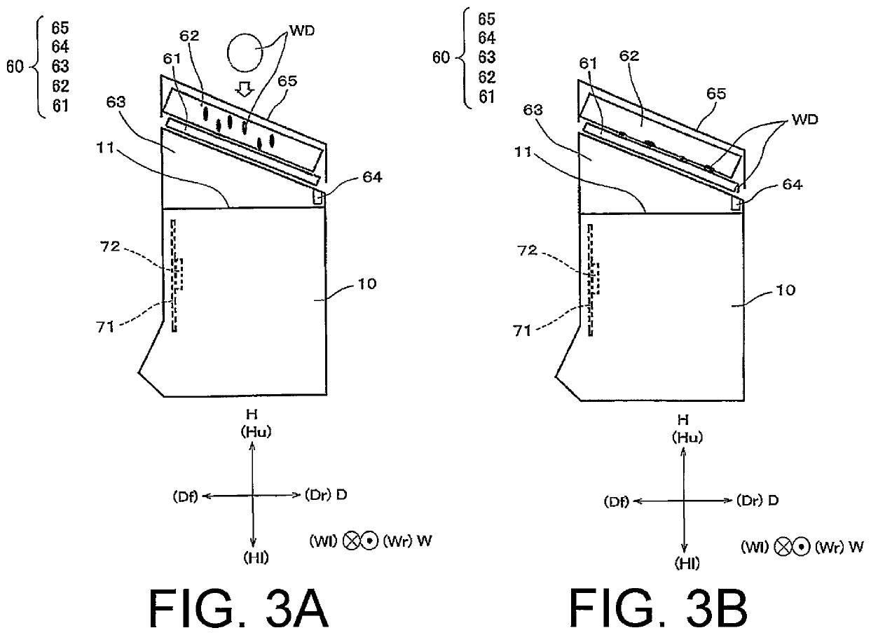

As shown in FIG. 3 (a), when the moisture WD falls down onto the top surface of the housing 10, the moisture WD is diffused inside the foam layer to become smaller water drops during passage through the second filter 62. The moisture WD is reduced in pressure or lowered in falling velocity.

Next, as shown in FIG. 3 (b), the moisture WD permeating the second filter 62 and reduced in pressure or falling velocity reaches the surface of the first filter 61 comprising the hydromesh layer. At the surface of the first filter 61, the moisture WD is repelled under surface tension. The moisture WD in the shape of the water drops flows along the slope of the first filter 61 in a rearward direction Dr and a downward direction Hl of the housing 10. Then, the moisture WD flowing down from the downslope edge of the first filter 61 is received by the gutter portion 64 and discharged along the extending direction of the gutter portion 64 (the width direction W of the housing 10). The gutter portion 64 may be inclined downward in the leftward direction W1 or the rightward direction Wr of the housing 10.

As described above, the moisture WD is prevented from intruding into the housing 10. In addition, incoming dust or foreign substances are also prevented by the second filter comprising the foam layer from intruding into the housing 10.

On the other hand, air exposed to heat conduction from the CPU 72 or the like generating heat in the housing 10 is discharged through the first filter 61 and the second filter 62 to the outside of the housing 10. Thus, heat release is achieved.

An object to which the waterproof structure for the ventilation opening of the electronic equipment according to the present invention is applicable is not limited to the gate device described above. For example, the waterproof structure according to the present invention is applicable to various types of electronic equipment, such as an oil feeding device in a self-service oil station system, which requires the ventilation opening of the housing to have breathability and to have a waterproof measure or a dustproof measure.

The present invention is based upon and claims the benefit of priority from Japanese patent application No. 2018-002378, filed on Jan. 11, 2018, the disclosure of which is incorporated herein in its entirety by reference.

### EXPLANATION OF REFERENCE NUMERALS

10 housing
11 ventilation opening
20 touch panel display
30 touch pad
40 power supply switch
50 speaker microphone
60 waterproof structure
61 first filter
62 second filter
63 frame member
64 gutter portion
64p peak
65 top cover
71 circuit board
72 CPU (Central Processing Unit)

What is claimed is:

1-10. (canceled)

11. A waterproof structure provided at a ventilation opening formed on a top surface of a housing of electronic equipment, the water proof structure comprising:
a first filter mounted to the ventilation opening to be inclined in a depth direction or a width direction of the housing; and
a gutter portion extending below a downslope edge of the first filter along the downslope edge,
wherein the first filter comprises a hydromesh layer having a hydrophobic or a water-repellent property and breathability, and
wherein the gutter portion is configured to receive moisture flowing down from a surface of the first filter and to discharge the moisture in an extending direction of the gutter portion.

12. The waterproof structure for the ventilation opening of the electronic equipment according to claim 11, wherein the gutter portion extends below a downslope edge of the first filter in parallel to the downslope edge.

13. The waterproof structure for the ventilation opening of the electronic equipment according to claim 11, wherein the gutter portion is inclined downward towards opposite ends thereof with a center in the extending direction as a peak.

14. The waterproof structure for the ventilation opening of the electronic equipment according claim 11, further comprising a frame member mounted to the ventilation opening to support the first filter so that the first filter is inclined in the depth direction or the width direction of the housing.

15. The waterproof structure for the ventilation opening of the electronic equipment according to claim 14, wherein the frame member is integral with the gutter portion.

16. The waterproof structure for the ventilation opening of the electronic equipment according to claim 11, further comprising:
a second filter mounted to the first filter to be stacked thereon,
the second filter comprising a foam layer having water absorbability and breathability.

17. The waterproof structure for the ventilation opening of the electronic equipment according to claim 16, further comprising:
a top cover mounted to the housing to cover the first filter and the second filter,
the top cover having a mesh-like or a grid-like shape with a plurality of holes formed at least on an upper surface thereof.

18. The waterproof structure for the ventilation opening of the electronic equipment according to claim 11, wherein the first filter is inclined downward towards a rear part of the housing in the depth direction.

19. The waterproof structure for the ventilation opening of the electronic equipment according to claim 12, further comprising a frame member mounted to the ventilation opening to support the first filter so that the first filter is inclined in the depth direction or the width direction of the housing.

20. The waterproof structure for the ventilation opening of the electronic equipment according to claim 19, wherein the frame member is integral with the gutter portion.

21. The waterproof structure for the ventilation opening of the electronic equipment according to claim 13, further comprising a frame member mounted to the ventilation opening to support the first filter so that the first filter is inclined in the depth direction or the width direction of the housing.

22. The waterproof structure for the ventilation opening of the electronic equipment according to claim 21, wherein the frame member is integral with the gutter portion.

23. The waterproof structure for the ventilation opening of the electronic equipment according to claim 12, further comprising:
a second filter mounted to the first filter to be stacked thereon,
the second filter comprising a foam layer having water absorbability and breathability.

24. The waterproof structure for the ventilation opening of the electronic equipment according to claim 13, further comprising:
a second filter mounted to the first filter to be stacked thereon,
the second filter comprising a foam layer having water absorbability and breathability.

25. The waterproof structure for the ventilation opening of the electronic equipment according to claim 14, further comprising:
a second filter mounted to the first filter to be stacked thereon,
the second filter comprising a foam layer having water absorbability and breathability.

26. The waterproof structure for the ventilation opening of the electronic equipment according to claim 15, further comprising:
a second filter mounted to the first filter to be stacked thereon,
the second filter comprising a foam layer having water absorbability and breathability.

27. The waterproof structure for the ventilation opening of the electronic equipment according to claim 12, wherein the first filter is inclined downward towards a rear part of the housing in the depth direction.

28. A housing of electronic equipment, comprising the waterproof structure for the ventilation opening of the electronic equipment according to claim 11.

29. An electronic equipment having the housing according to claim 28.

30. The electronic equipment according to claim 29, further comprising:
at least one electronic component which generates heat following an operation of the electronic equipment,
the electronic component being accommodated in the housing so that an upper part of the electronic component faces the ventilation opening.
